(19) United States
(12) Patent Application Publication
(10) Pub. No.: US 2015/0236293 A1
(43) Pub. Date: Aug. 20, 2015

(54) ORGANIC LIGHT EMITTING DISPLAY DEVICE AND METHOD OF MANUFACTURING THE SAME

(71) Applicant: Samsung Display Co., Ltd., Yongin-City (JP)

(72) Inventors: Jae-Man Lee, Anyang-si (KR); Jin-Woo Park, Yongin-si (KR); Sang-Wook Sin, Suwon-si (KR); Seung-Joon Yoo, Suwon-si (KR); Jae-Sun Lee, Cheonan-si (KR)

(21) Appl. No.: 14/532,605

(22) Filed: Nov. 4, 2014

(30) Foreign Application Priority Data
Feb. 19, 2014 (KR) 10-2014-0018922

(51) Int. Cl. H01L 51/52

(52) U.S. Cl. CPC H01L 51/524; H01L 51/0024

(57) ABSTRACT

An organic light emitting display device includes a first substrate, a second substrate opposing the first substrate, a plurality of organic light emitting diodes disposed on the first substrate, a protection layer covering the organic light emitting diodes, an inner filling layer disposed between the protection layer and the second substrate, the inner filling layer including a hardened monomer material, and a sealing member located between the first substrate and the second substrate to seal between the first substrate and the second substrate, the sealing member enclosing the organic light emitting diodes, the protection layer, and the inner filling layer.

### CLAIM OF PRIORITY

This application claims priority under 35 U.S.C. §119 to Korean patent Application No. 10-2014-0018922 filed on Feb. 19, 2014, the disclosure of which is hereby incorporated by reference herein in its entirety.

### BACKGROUND OF THE INVENTION

1. Field of the Invention

Embodiments of the present invention generally relate to display devices. More particularly, embodiments of the present invention relate to an organic light emitting display device and a method of manufacturing the organic light emitting display device.

2. Description of the Related Art

An organic light emitting diode (OLED) element may include an organic layer between two electrodes, namely, an anode and a cathode. Positive holes from the anode may be combined with electrons from the cathode in the organic layer between the anode and the cathode to emit light. The OLED element may have a variety of advantages such as a wide viewing angle, a rapid response speed, relatively thin thickness, and low power consumption.

An organic light emitting diode (OLED) is sensitive to moisture and gas. Thus, when the OLED is exposed to moisture and gas, the characteristic of the OLED may be deteriorated, and the life span of the OLED may be shortened. Therefore, techniques that can isolate the OLED from an external environment including moisture and gas have been developed recently. The OLED in a display device can be isolated from the external environment using a frit. For example, since a cavity of the frit is smaller than a water molecule, the display device that is sealed by the frit can be isolated from the moisture, thereby preventing the deterioration of the OLED. However, the display device sealed by the frit has low peel strength due to low adhesion between the frit and a substrate of the display device.

### SUMMARY OF THE INVENTION

Embodiments of the present invention provide an organic light emitting display device capable of improving the durability.

Embodiments of the present invention provide a method of manufacturing the organic light emitting display device.

According to some embodiments, an organic light emitting display device may include a first substrate, a second substrate opposing the first substrate, a plurality of organic light emitting diodes disposed on the first substrate, a protection layer covering the organic light emitting diodes, an inner filling layer disposed between the protection layer and the second substrate, the inner filling layer including a hardened monomer material, and a sealing member located between the first substrate and the second substrate to seal between the first substrate and the second substrate, the sealing member enclosing the organic light emitting diodes, the protection layer, and the inner filling layer.

In some embodiments, the hardened monomer material included in the inner filling layer may be generated by hardening a monomer after combining the first substrate and the second substrate.

In some embodiments, the hardened monomer material may include at least one of a hardened acrylic monomer, a hardened silicon monomer, and a hardened epoxy monomer.

In some embodiments, the protection layer may include a first organic layer covering the organic light emitting diodes, the first organic layer including the hardened monomer material, and a second organic layer covering the first organic layer, the second organic layer including the hardened monomer material.

In some embodiments, a thickness of the second organic layer may be greater than a thickness of the first organic layer.

In some embodiments, the sealing member may include a frit.

In some embodiments, the protection layer may include a first inorganic layer covering the organic light emitting diodes, a third organic layer disposed on the first inorganic layer, and a second inorganic layer covering the third organic layer.

In some embodiments, the first inorganic layer and the second inorganic layer may include at least one of silicon oxide (SiOx), silicon nitride (SiNx), titanium oxide (TiOx), aluminum oxide (AlOx), and silicon oxynitride (SiOxNy).

In some embodiments, the sealing member may include an epoxy resin.

In some embodiments, the first inorganic layer may contact with the second inorganic layer in an outer region of the organic light emitting diodes, and the second inorganic layer may contact with the sealing member in the outer region of the organic light emitting diodes.

In some embodiments, the organic light emitting display device may further include a reinforcing member enclosing the sealing member, the reinforcing member located between the first substrate and the second substrate to seal between the first substrate and the second substrate.

According to some embodiments, a method of manufacturing an organic light emitting display device may include a step of forming a plurality of organic light emitting diodes on a first substrate, a step of forming a protection layer that covers the organic light emitting diodes, a step of forming an inner filling layer on the protection layer, the inner filling layer including a monomer, a step of combining the first substrate and a second substrate opposing the first substrate, a step of hardening the inner filling layer after the first substrate and the second substrate are combined, and a step of sealing between the first substrate and the second substrate by a sealing member that is located between the first substrate and the second substrate, the sealing member enclosing the organic light emitting diodes, the protection layer, and the inner filling layer.

In some embodiments, the step of forming the protection layer may include a step of forming a first organic layer including the monomer to cover the organic light emitting diodes, a step of hardening the first organic layer, a step of forming a second organic layer including the monomer to cover the first organic layer, and a step of hardening the second organic layer.

In some embodiments, a thickness of the second organic layer may be greater than a thickness of the first organic layer.

In some embodiments, the sealing member may include a frit.

In some embodiments, the step of forming the protection layer may include a step of forming a first inorganic layer that covers the organic light emitting diodes, a step of forming a third organic layer that includes the monomer on the first inorganic layer, and a step of hardening the third organic layer, and a step of forming a second inorganic layer that covers the third organic layer.

In some embodiments, the first inorganic layer and the second inorganic layer may be formed by a chemical vapor deposition (CVD) method.

In some embodiments, the first inorganic layer and the second inorganic layer may include at least one of silicon oxide (SiOx), silicon nitride (SiNx), titanium oxide (TiOx), aluminum oxide (AlOx), and silicon oxynitride (SiOxNy).

In some embodiments, the sealing member may include an epoxy resin.

In some embodiments, the monomer included in the inner filling layer may include at least one of an acrylic monomer, a silicon monomer, and an epoxy monomer.

Therefore, the organic light emitting display device according to example embodiments may have high peel strength by including the protection layer and inner filling layer.

In addition, the method of manufacturing the organic light emitting display device according to example embodiments may improve the durability of the organic light emitting display device by hardening the inner filling layer including the monomer after the first substrate and the second substrate are combined.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a plan view illustrating an organic light emitting display device according to example embodiments;

FIG. 2 is a cross-sectional view illustrating one example of a view taken along the line I-I′ of FIG. 1;

FIG. 3 is an enlarged view illustrating an example of a portion ‘A’ of FIG. 2;

FIG. 4 is a flow chart illustrating a method of manufacturing an organic light emitting display device according to one example embodiment;

FIGS. 5A through 5C are cross-sectional views illustrating an example of a method of manufacturing an organic light emitting display device of FIG. 4;

FIG. 6 is a graph for describing an effect of a method of manufacturing an organic light emitting display device of FIG. 4;

FIG. 7 is a cross-sectional view illustrating another example of a view taken along the line I-I′ of FIG. 1;

FIG. 8 is an enlarged view illustrating an example of a portion ‘B’ of FIG. 7;

FIG. 9 is a flow chart illustrating a method of manufacturing an organic light emitting display device according to another example embodiment;

FIGS. 10A through 10D are cross-sectional views illustrating an example of a method of manufacturing an organic light emitting display device of FIG. 9; and

FIG. 11 is a graph for describing an effect of a method of manufacturing an organic light emitting display device of FIG. 9.

### DETAILED DESCRIPTION OF THE INVENTION

Exemplary embodiments will be described more fully hereinafter with reference to the accompanying drawings, in which various embodiments are shown.

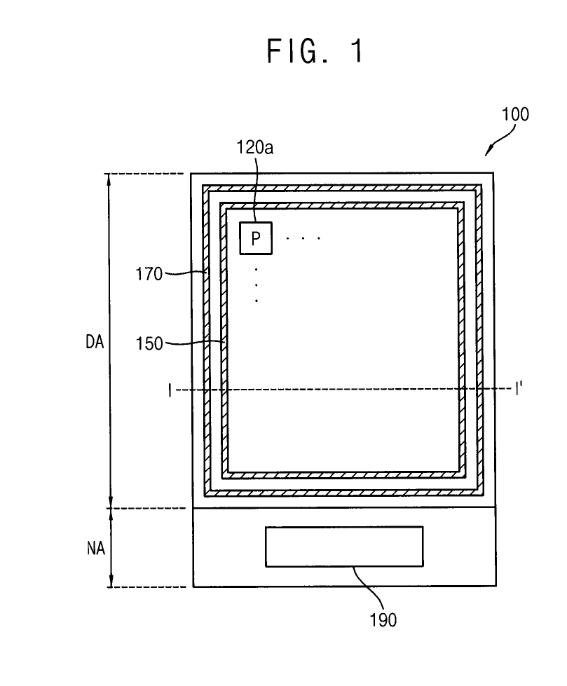

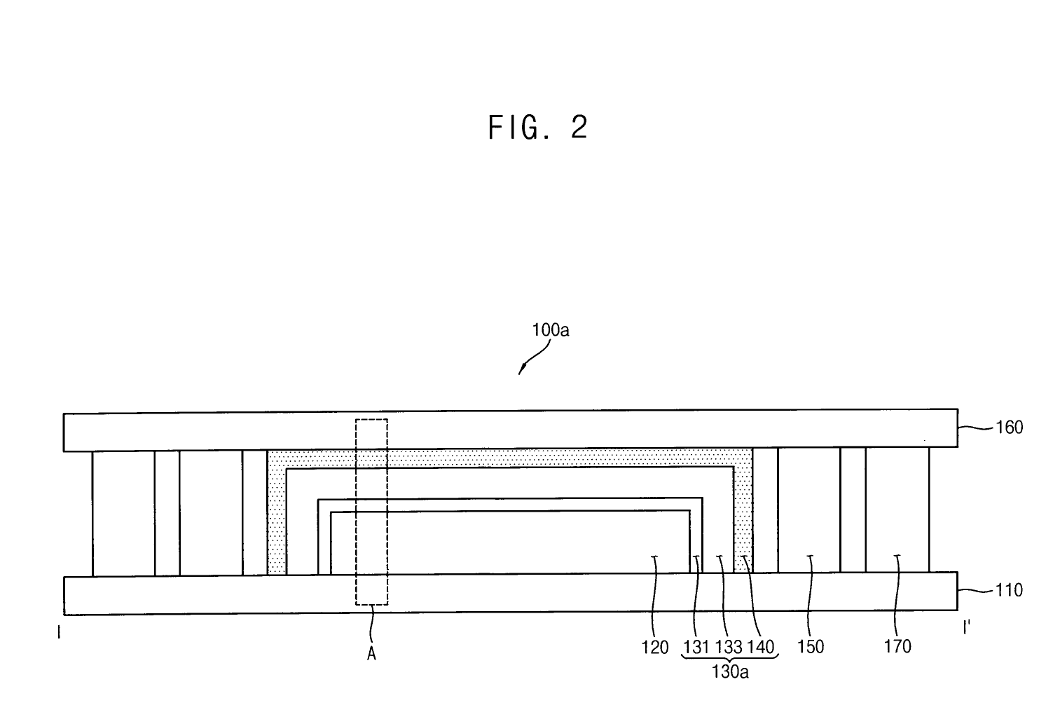

FIG. 1 is a plan view illustrating an organic light emitting display device according to embodiments of the present invention. FIG. 2 is a cross-sectional view illustrating one example of a view taken along the line I-I′ of FIG. 1.

Referring to FIGS. 1 and 2, an organic light emitting display device 100a may include a first substrate 110, a plurality of organic light emitting diodes 120, a protection layer 130a, an inner filling layer 140, a sealing member 150, and a second substrate 160.

The first substrate 110 may be disposed oppose to the second substrate 160. One of the first substrate 110 and the second substrate 160 may be a base substrate on which the plurality of organic light emitting diodes 120 are formed, and the other of the first substrate 110 and the second substrate 160 may be an encapsulation substrate. The first substrate 110 or the second substrate 160 may include a transparent insulation substrate. For example, the first substrate 110 or the second substrate 160 may include a glass substrate, a quartz substrate, a transparent resin substrate, etc. The transparent resin substrate may include polyamide resin, acryl resin, polyacrylate resin, polycarbonate resin, polyether resin, polyethylene terephthalate resin, sulfonic acid resin, etc.

The organic light emitting diodes 120 may be disposed on a display region DA of the first substrate 110. Each organic light emitting diode 120a may be electrically coupled to a driving circuit 190 disposed on the non-display region NA via signal lines (not shown in FIGS. 1 and 2). The organic light emitting diodes 120a may receive driving signals from the driving circuit 190 to display images.

The protection layer 130a may cover the organic light emitting diodes 120 to protect the organic light emitting diodes 120. The protection layer 130a may include a first organic layer 131 covering the organic light emitting diodes 120 and a second organic layer 133 covering the first organic layer 131. The first organic layer 131 and the second organic layer 133 may include a hardened monomer material. The hardened monomer material is formed by hardening a monomer. In one embodiment, the hardened monomer material may include at least one of a hardened acrylic monomer, a hardened silicon monomer, and a hardened epoxy monomer. The first organic layer 131 may cover the organic light emitting diodes 120 to protect the organic light emitting diodes 120. Therefore, the life span of the organic light emitting diodes 120 may be extended by the first organic layer 131. The second organic layer 133 may cover the first organic layer 131 to further protect the organic light emitting diodes 120. In addition, the second organic layer 133 may act as a planarization layer to stably form the inner filling layer 140 on the second organic layer 133. In one embodiment, a thickness of the second organic layer 133 may be greater than a thickness of the first organic layer 131. More specifically, the thickness of the second organic layer 133 may be about 10 times or more of the thickness of the first organic layer 131. For example, the thickness of the first organic layer 131 may be about 0.2 μm, and the thickness of the second organic layer 133 may be about 3 μm. Therefore, the protection layer 130a may include a plurality of organic layers to protect the organic light emitting diodes 120, thereby extending the life span of the organic light emitting diodes 120 and stably forming the inner filling layer 140 on the protection layer 130a.

The inner filling layer 140 may be disposed between the protection layer 130a and the second substrate 160 and may include the hardened monomer material. In one embodiment, the hardened monomer material included in the inner filling layer 140 is formed by hardening a monomer after stacking the first substrate 110 and the second substrate 160 together. Thus, the unhardened monomer included in the inner filling layer 140 may be hardened by UV rays or other methods after stacking the first substrate 110 and the second substrate 160, thereby bonding the first substrate 110 and the second substrate 160. In addition, the inner filling layer 140 may prevent deformation of the substrates 110 and 160, because the inner filling layer 140 fills the empty space between the protection layer 130a and the second substrate 160. That is, the inner filling layer 140 may directly contact the protection layer 130a and the second substrate 160. More specifically, any portions of the inner filling layer 140, which overlap a region where all organic light emitting diodes 120 are formed, may directly contact the protection layer 130a and the second substrate 160. Therefore, the inner filling layer 140 may prevent peeling defects that is generated by broadening a gap between the first substrate 110 and the second substrate 160. The inner filling layer 140 may include the hardened monomer material to protect the organic light emitting diodes 120. In one embodiment, the hardened monomer material may include at least one of a hardened acrylic monomer, a hardened silicon monomer, and a hardened epoxy monomer.

The sealing member 150 may be located between the first substrate 110 and the second substrate 160 to seal between the first substrate 110 and the second substrate 160. The sealing member 150 may enclose the organic light emitting diodes 120, the protection layer 130a, and the inner filling layer 140. In one embodiment, the sealing member 150 may include a frit. When the protection layer 130a includes a plurality of organic layers, the moisture and gas may permeate through the organic light emitting diodes 120. Therefore, the sealing member 150 may include the frit to prevent permeation of moisture and gas through the organic light emitting diodes 120. If the sealing member 150 contacts with the protection layer 130a including the organic material, an adhesion between the sealing member 150 and the substrates 110 and 160 may be decreased. Therefore, the sealing member 150 may be spaced apart from the protection layer 130a and the inner filling layer 140.

The organic light emitting display device 100a may further include the driving circuit 190 that provides the driving signal to drive the organic light emitting diodes 120. In one embodiment, the driving circuit 190 may be directly mounted on the first substrate 110 without additional structures by chip-on-glass (COG) method. For example, the driving circuit 190 may be mounted on the non-display region NA of the first substrate 110 using an anisotropic conductive film (ACF).

The organic light emitting display device 100a may further include a reinforcing member 170. The reinforcing member 170 may enclose the sealing member 150 and may be located between the first substrate 110 and the second substrate 160 to seal between the first substrate and 110 the second substrate 160.

Although it is illustrated in FIG. 2 that the protection layer 130a includes the first organic layer 131 and the second organic layer 133, the protection layer 130a may have various structures that include at least one organic layer. In one embodiment, the protection layer 130a may further include additional layers in addition to the first organic layer 131 and the second organic layer 133. In another embodiment, the protection layer 130a may be single organic layer that includes the hardened monomer material.

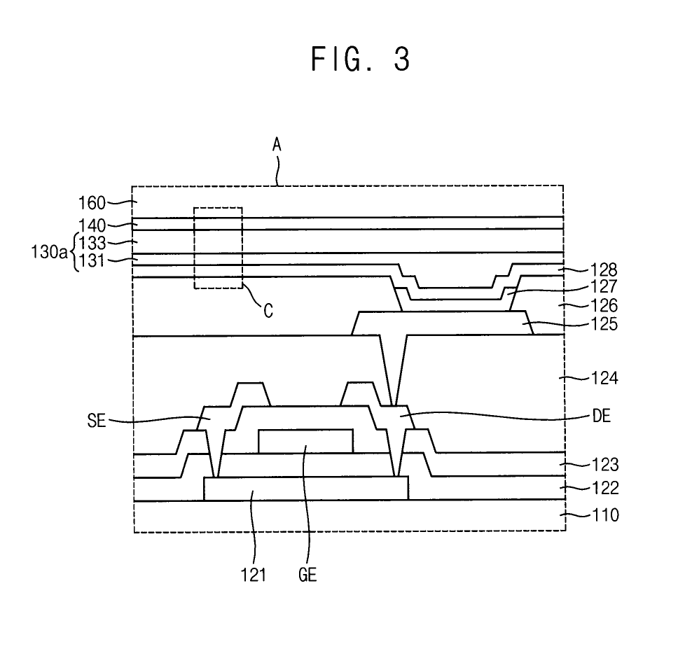

FIG. 3 is an enlarged view illustrating a portion ‘A’ of FIG. 2.

Referring to FIG. 3, a pixel unit of an organic light emitting display device may include a first substrate 110, a thin-film transistor disposed on the first substrate 110, an organic light emitting diode that is electrically coupled to the thin-film transistor, a protection layer 130a, a inner filling layer 140 disposed on the protection layer 130a, and a second substrate 160.

The thin-film transistor may include an active layer 121, a gate insulation layer 122, gate electrode GE, an inorganic insulation layer 123, a source electrode SE, and a drain electrode DE. The active layer 121 may include amorphous silicon, poly silicon or organic semiconductor materials. The gate insulation layer 122 may be disposed on the active layer 121. The gate electrode GE may be disposed on the gate insulation layer 122 and may overlap the active layer 121. The inorganic insulation layer 123 may be disposed on the gate electrode GE and may entirely cover the gate electrode GE. The source electrode SE may be electrically connected to the active layer 121 through a first contact hole that is formed in the gate insulation layer 122 and the inorganic insulation layer 123. For example, the source electrode SE may contact a first end portion of the active layer 121. In addition, the source electrode SE may partially overlap a first end portion of the gate electrode GE. The drain electrode DE may be electrically connected to the active layer 121 through a second contact hole that is formed in the gate insulation layer 122 and the inorganic insulation layer 123. For example, the drain electrode DE may contact a second end portion of the active layer 121. In addition, the drain electrode DE may partially overlap a second end portion of the gate electrode GE. The organic insulation layer 124 may be disposed on the inorganic insulation layer 123 on which the source electrode SE and the drain electrode DE are formed.

The organic light emitting diode may include a first electrode 125, an intermediate layer 127, and a second electrode 128. The first electrode 125 may be disposed on the organic insulation layer 124. The first electrode 125 may be electrically connected to the drain electrode DE. In one embodiment, the first electrode 125 may be used as an anode that provides positive holes. The intermediate layer 127 may be disposed on the first electrode 125. The intermediate layer 127 may sequentially include a hole injection layer (HIL), a hole transfer layer (HTL), an emission layer (EML), an electron transfer layer (ETL) and an electron injection layer (EIL). The first electrode 125 provides positive holes to the HIL and the HTL. The second electrode 128 provides electrons to the ETL and the EIL. The positive holes are combined with the electrons in the EML to generate light having a desired wavelength. The second electrode 128 may be disposed on the intermediate layer 127. In an embodiment, the second electrode 128 may be used as a cathode that provides electrons.

The pixel defining layer 126 may be disposed on the organic insulation layer 124 on which the first electrode 125 is formed. The pixel defining pattern 126 may partially overlap two end portions of the first electrode 125.

The protection layer 130a may be disposed on the organic light emitting diode. The inner filling layer 140 may be disposed on the protection layer 130a. The protection layer 130a may include the first organic layer 131 and the second organic layer 133. The protection layer 130a including the first organic layer 131 and the second organic layer 133, and the inner filling layer 140 are described above, duplicated descriptions will be omitted.

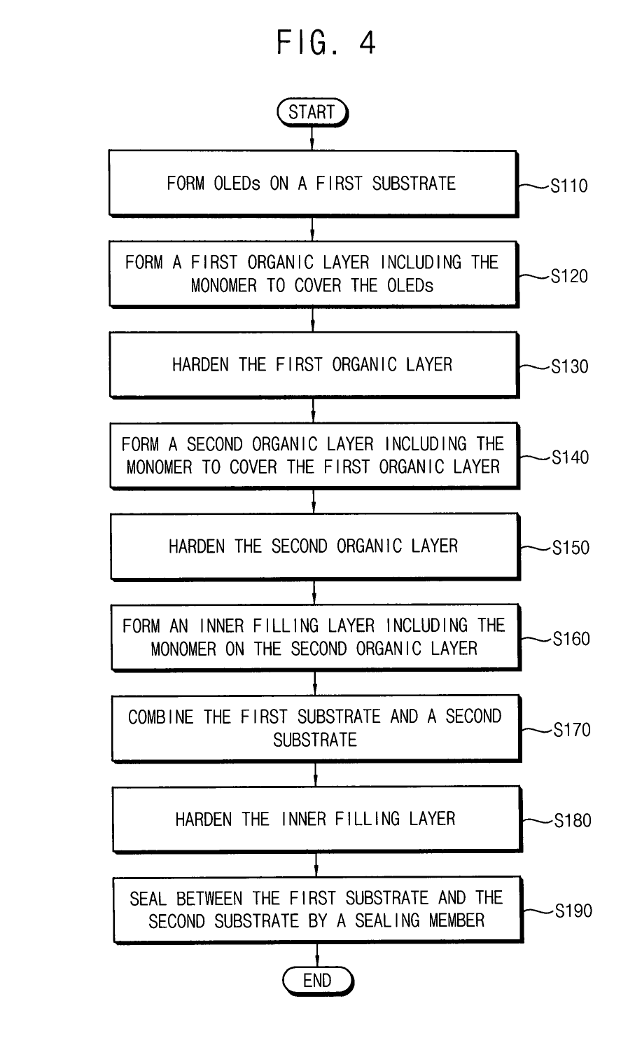

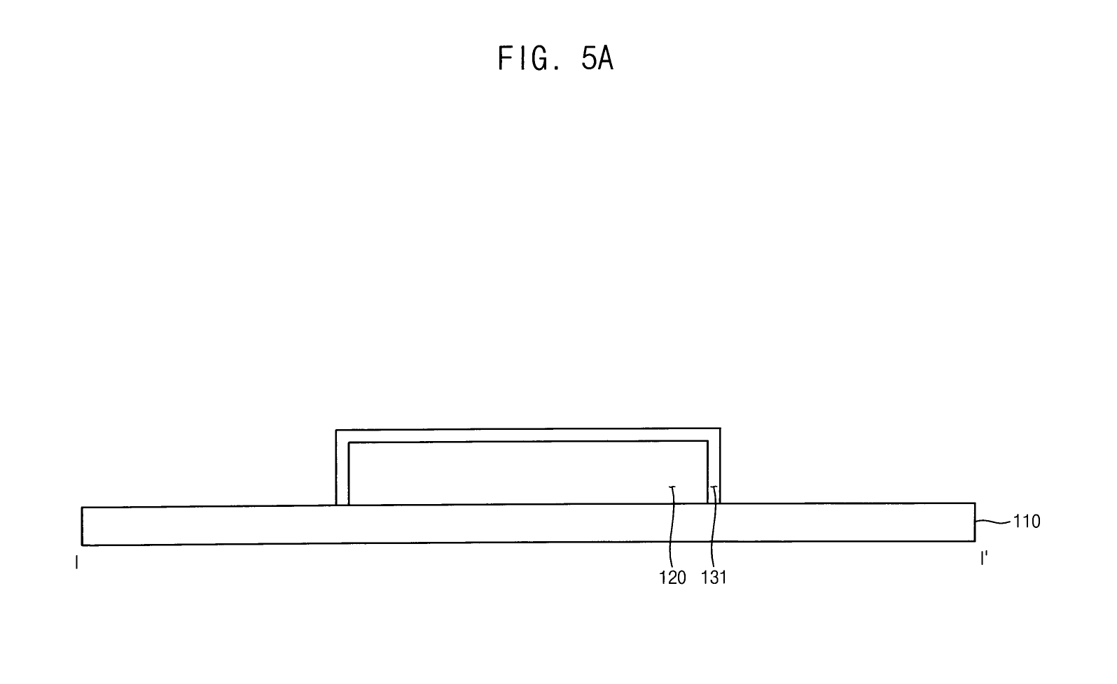

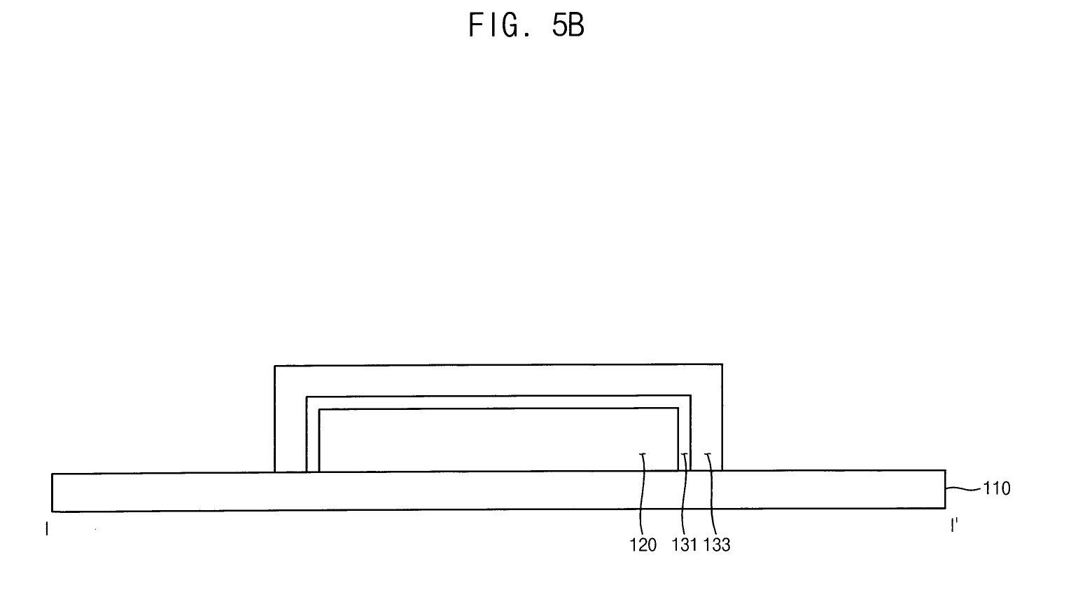

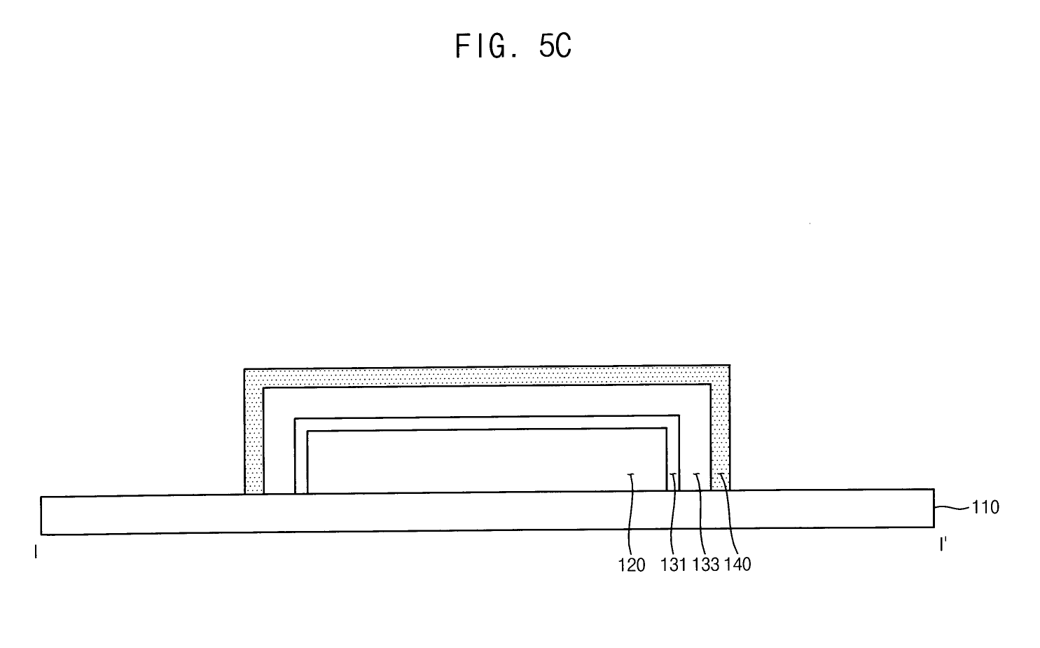

FIG. 4 is a flow chart illustrating a method of manufacturing an organic light emitting display device according to one embodiment. FIGS. 5A through 5C are cross-sectional views illustrating an example of a method of manufacturing an organic light emitting display device of FIG. 4.

Referring to FIGS. 2, and 4 through 5C, the method of manufacturing the organic light emitting display device may include a step of forming the organic light emitting diodes 120 and thin-film transistors on the first substrate 110 (S110), a step of forming the first organic layer 131 including monomer to cover the organic light emitting diodes 120 (S120), a step of hardening the first organic layer 131 (S130), a step of forming the second organic layer 133 including monomer to cover the first organic layer 131 (S140), a step of hardening the second organic layer 133 (S150), a step of forming the inner filling layer 140 including monomer on the second organic layer 133 (S160), a step of combining the first substrate 110 and the second substrate 160 (S170), a step of hardening the inner filling layer 140 (S180), and a step of sealing between the first substrate 110 and the second substrate 160 by a sealing member 150 (S190).

As shown in FIG. 5A, the organic light emitting diodes 120 and thin-film transistors (not shown in FIG. 5A) may be formed on the first substrate 110. The first organic layer 131 may be formed to cover the organic light emitting diodes 120.

The organic light emitting diodes 120 may be formed on the first substrate 110 on which the thin-film transistors are formed. Each of the organic light emitting diodes 120 may include a first electrode, an intermediate layer, and a second electrode.

The first organic layer 131 that includes an unhardened monomer material may be formed to cover the organic light emitting diodes 120. The first organic layer 131 that is unhardened status may be hardened by UV rays or other methods to protect the organic light emitting diodes 120. Thus, the unhardened monomer included in the first organic layer 131 may be hardened by UV rays or other methods after the first organic layer 131 is formed to cover the organic light emitting diodes 120.

As shown in FIG. 5B, the second organic layer 133 including an unhardened monomer may cover the first organic layer 131. The second organic layer 133 may be hardened by UV rays or other methods. Thus, the unhardened monomer included in the second organic layer 133 may be hardened by UV rays or other methods after the second organic layer 133 is formed to cover the first organic layer 131. The second organic layer 133 may protect the organic light emitting diodes 120 and may act as a planarization layer to stably form the inner filling layer 140 on the second organic layer 133. In one embodiment, a thickness of the second organic layer 133 may be greater than a thickness of the first organic layer 131. More specifically, the thickness of the second organic layer 133 may be about 10 or more times of the thickness of the first organic layer 131. For example, the thickness of the first organic layer 131 may be about 0.2 μm, and the thickness of the second organic layer 133 may be about 3 μm. Therefore, the first organic layer 131 and the second organic layer 133 may be used as the protection layer to protect the organic light emitting diodes 120.

As shown in FIG. 5C, the inner filling layer 140 including an unhardened monomer may be formed on the second organic layer 133. The inner filling layer 140 may be hardened after combining the first substrate 110 and the second substrate 160. Thus, the unhardened monomer included in the inner filling layer 140 may be hardened by UV rays or other methods after combining the first substrate 110 and the second substrate 160, thereby bonding the first substrate 110 and the second substrate 160. In addition, the inner filling layer 140 may prevent deformation of the organic light emitting display device by an external impact. Therefore, the inner filling layer 140 that is hardened may protect the organic light emitting diodes 120 by including hardened monomer material. In one embodiment, the monomer included in the inner filling layer 140 may include at least one of an acrylic monomer, a silicon monomer, and an epoxy monomer.

The first substrate 110 and the second substrate 160 may be combined by the sealing member 150. The sealing member 150 may be enclosed the organic light emitting diodes 120, the first organic layer 131, the second organic layer 133, and the inner filling layer 140. In one embodiment, the sealing member 150 may include a frit. When the protection layer is comprised of the first organic layer 131 and the second organic layer 133, the moisture and gas may permeate through the organic light emitting diodes 120. Therefore, the sealing member 150 may include the frit to prevent permeation of moisture and gas through the organic light emitting diodes 120.

In this way, the organic light emitting display device of FIG. 2 is manufactured. In addition, the organic light emitting display device may further include a reinforcing member 170. The reinforcing member 170 may enclose the sealing member 150 and may be located between the first substrate 110 and the second substrate 160 to seal between the first substrate 110 and the second substrate 160.

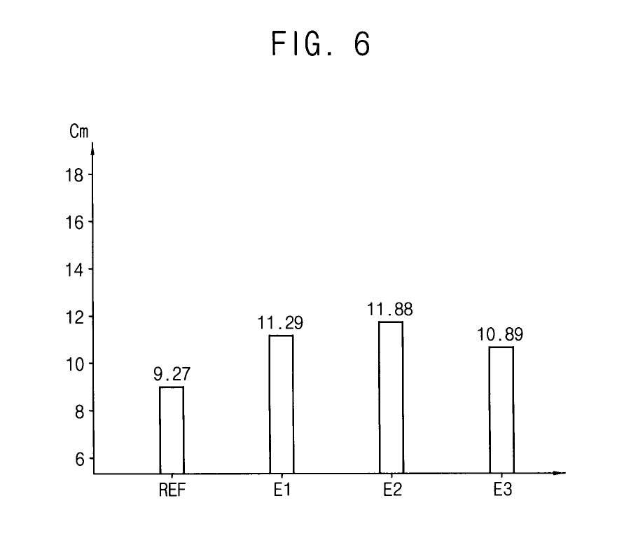

FIG. 6 is a graph for describing an effect of a method of manufacturing an organic light emitting display device of FIG. 4.

Referring to FIG. 6, the organic light emitting display device that is manufactured by the method of FIG. 4 may have a high durability.

The drop weight test, that measures a height in which the organic light emitting display device is fragile when the urethane ball having 300 g weight is dropped, was performed. In a comparative example, a comparative organic light emitting display device REF is sealed between the substrates using the frit without the protection layer and the inner filling layer. In this case, there is an empty space between the organic light emitting diodes and one of the substrates. A height, in which the comparative organic light emitting display device REF is fragile, was average 9.27 cm. In the first experimental example, the first experimental organic light emitting display device E1 includes the first organic layer of which thickness is 0.2 μm, the second organic layer of which thickness is 3.8 μm, and the inner filling layer of which thickness is 0.5 μm. A height, in which the first experimental organic light emitting display device E1 is fragile, was average 11.29 cm. In the second experimental example, the second experimental organic light emitting display device E2 includes the first organic layer of which thickness is 0.2 μm, the second organic layer of which thickness is 3.3 μm, and the inner filling layer of which thickness is 1 μm. A height, in which the second experimental organic light emitting display device E2 is fragile, was average 11.88 cm. In the third experimental example, the third experimental organic light emitting display device E3 includes the first organic layer of which thickness is 0.2 μm, the second organic layer of which thickness is 2.8 μm, and the inner filling layer of which thickness is 1 μm. A height, in which the third experimental organic light emitting display device E3 is fragile, was average 10.89 cm. Here, each thickness is determined in a region where the pixel defining layer 126 is formed, for example, region C shown in FIG. 3.

Therefore, the experimental organic light emitting display devices E1 E2 E3 that are manufactured by the method of FIG. 4 have a relative high durability in comparison with the comparative organic light emitting display device REF. The organic light emitting display device has high durability in proportion to the total thickness of the first organic layer, the second organic layer, and the inner filling layer. Also, when the organic light emitting display device has the relatively thick inner filling layer under the same total thickness, the organic light emitting display device has relative high durability.

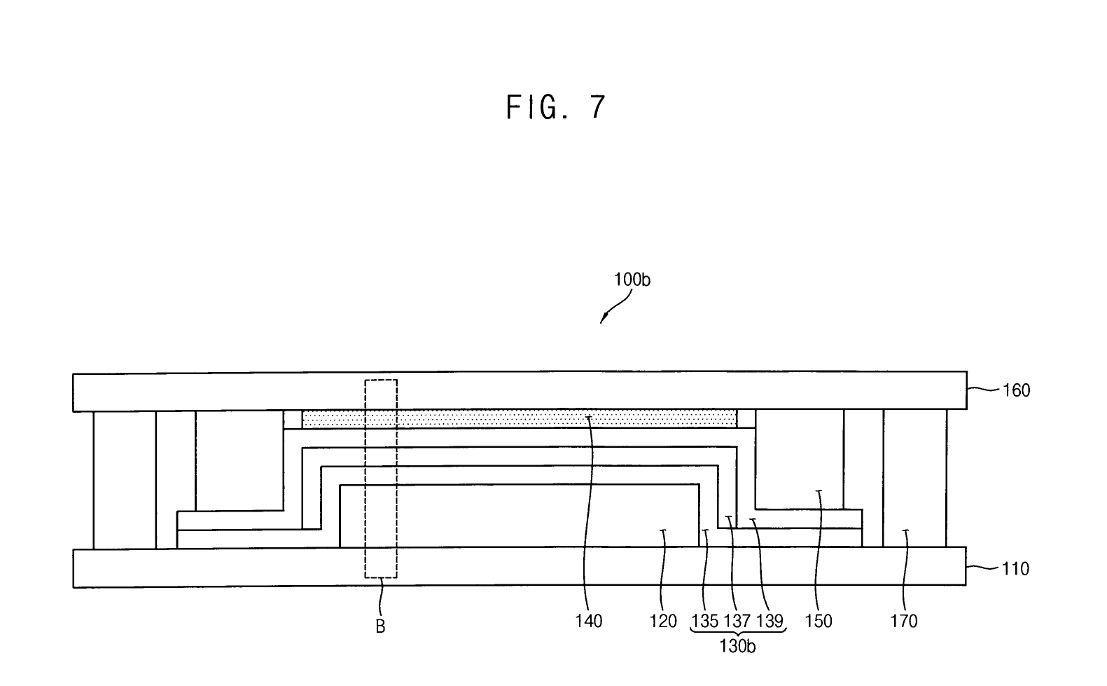

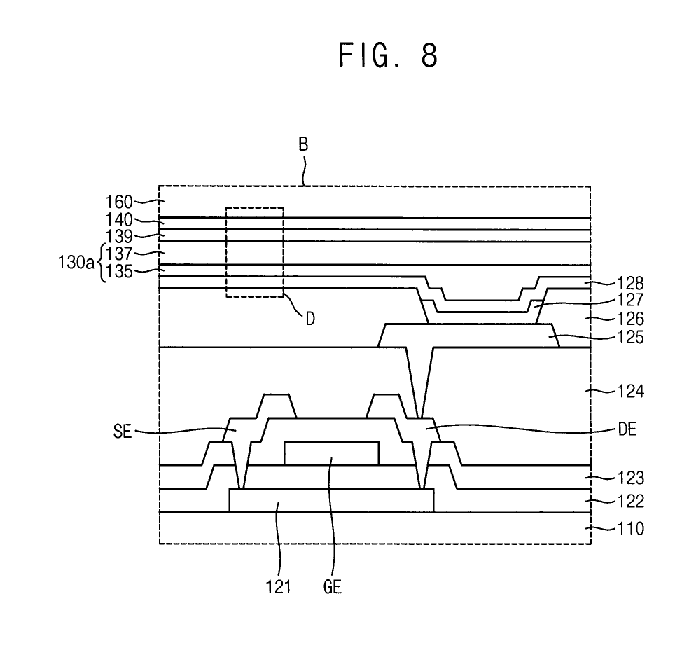

FIG. 7 is a cross-sectional view illustrating another example of a view taken along the line I-I′ of FIG. 1. FIG. 8 is an enlarged view illustrating an example of a portion ‘B’ of FIG. 7.

Referring to FIGS. 1, 7, and 8, the organic light emitting display device 100b may include a first substrate 110, a plurality of organic light emitting diodes 120, a protection layer 130b, an inner filling layer 140, a sealing member 150, and a second substrate 160. The organic light emitting display device 100b according to the present embodiment is substantially the same as the organic light emitting display device of the exemplary embodiment described in FIG. 2, except the protection layer 130b and the sealing member 150. Therefore, the same reference numerals will be used to refer to the same or like parts as those described in the previous exemplary embodiment of FIG. 2, and any repetitive explanation concerning the above elements will be omitted.

The protection layer 130b may cover the organic light emitting diodes 120 to protect the organic light emitting diodes 120. The protection layer 130b may include a first inorganic layer 135 covering the organic light emitting diodes 120, a third organic layer 137 disposed on the first inorganic layer 135, and a second inorganic layer 139 covering the third organic layer 137.

The first inorganic layer 135 and the second inorganic layer 139 may effectively prevent the permeation of moisture and gas, because the first inorganic layer 135 and the second inorganic layer 139 have high density. In one embodiment, the first inorganic layer 135 and the second inorganic layer 139 may include at least one of silicon oxide (SiOx), silicon nitride (SiNx), titanium oxide (TiOx), aluminum oxide (AlOx), and silicon oxynitride (SiOxNy). The third organic layer 137 may include the hardened monomer material. In one embodiment, the hardened monomer material included in the third organic layer 137 may include at least one of a hardened acrylic monomer, a hardened silicon monomer, and a hardened epoxy monomer. The third organic layer 137 may act as a buffer layer. Thus, the third organic layer 137 may reduce the stress between the first inorganic layer 135 and the second inorganic layer 139. Therefore, the protection layer 130b sequentially including the first inorganic layer 135, the third organic layer 137, and the second inorganic layer 139 may protect the organic light emitting diodes 120 from the moisture and gas and may reduce the impact.

The inner filling layer 140 may be disposed between the protection layer 130b and the second substrate 160 and may include a hardened monomer material. In one embodiment, the hardened monomer material included in the inner filling layer 140 is generated by hardening a monomer after combining the first substrate 110 and the second substrate 160. The inner filling layer 140 are described above, duplicated descriptions will be omitted.

The sealing member 150 may be located between the first substrate 110 and the second substrate 160 to seal between the first substrate 110 and the second substrate 160. The sealing member 150 may enclose the organic light emitting diodes 120, the protection layer 130b, and the inner filling layer 140. In one embodiment, the sealing member 150 may include an epoxy resin. Because the protection layer 130b including the first inorganic layer 135 and the second inorganic layer 139 prevents the permeation of moisture and gas through the organic light emitting diodes 120, the sealing member 150 may include an epoxy resin that has high adhesion with the substrates instead of the frit that has low adhesion with the substrates.

In one embodiment, the first inorganic layer 135 may contact with the second inorganic layer 139 in an outer region of the organic light emitting diodes 120. The second inorganic layer 139 may contact with the sealing member 150 in the outer region of the organic light emitting diodes 120. Because the first inorganic layer 135 and the second inorganic layer 139 have relatively high adhesion with each other, the first inorganic layer 135 may contact with the second inorganic layer 139 in an outer region of the organic light emitting diodes 120. In addition, the second inorganic layer 139 may contact with the sealing member 150 including the epoxy resin in the outer region of the organic light emitting diodes 120 to reduce the empty space in the display unit of the organic light emitting display device 100b and to improve the durability of the organic light emitting display device 100b.

In some embodiments, the organic light emitting display device 100b may further include a reinforcing member 170. The reinforcing member 170 may enclose the sealing member 150 and may be located between the first substrate 110 and the second substrate 160 to seal between the first substrate 110 and the second substrate 160.

Although it is illustrated in FIG. 7 and FIG. 8 that the protection layer 130b includes the first inorganic layer 135, the third organic layer 137, and the second inorganic layer 139, the protection layer 130b may have various structures that have a thin film encapsulation structure. In one embodiment, the protection layer 130b may include a plurality of organic layers and a plurality of inorganic layers that are disposed alternately. In another example embodiment, the protection layer 130b may be single inorganic layer.

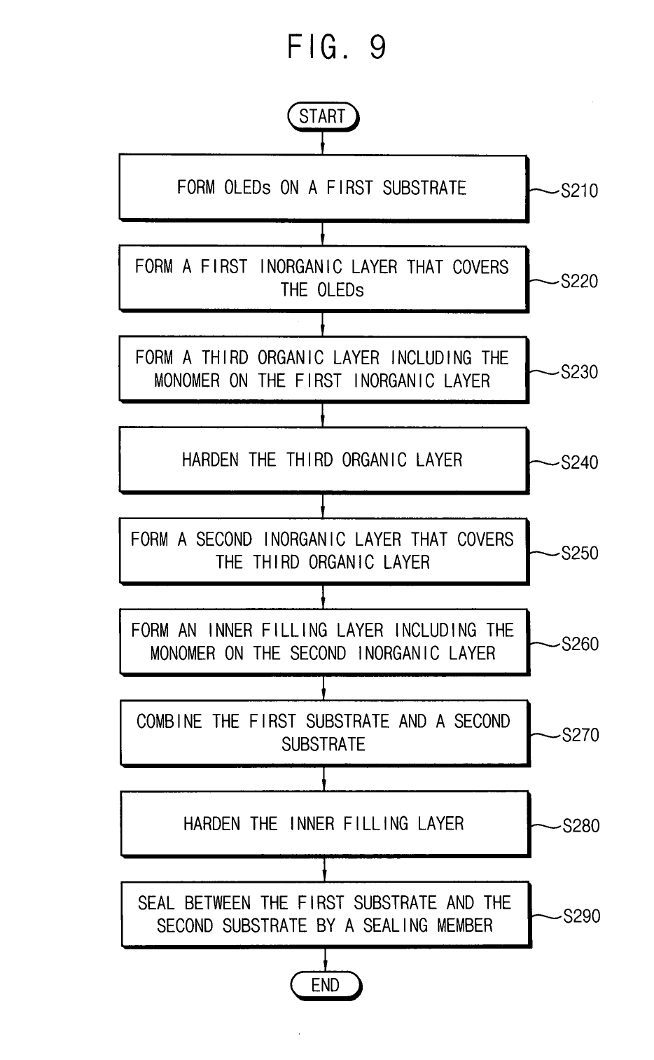

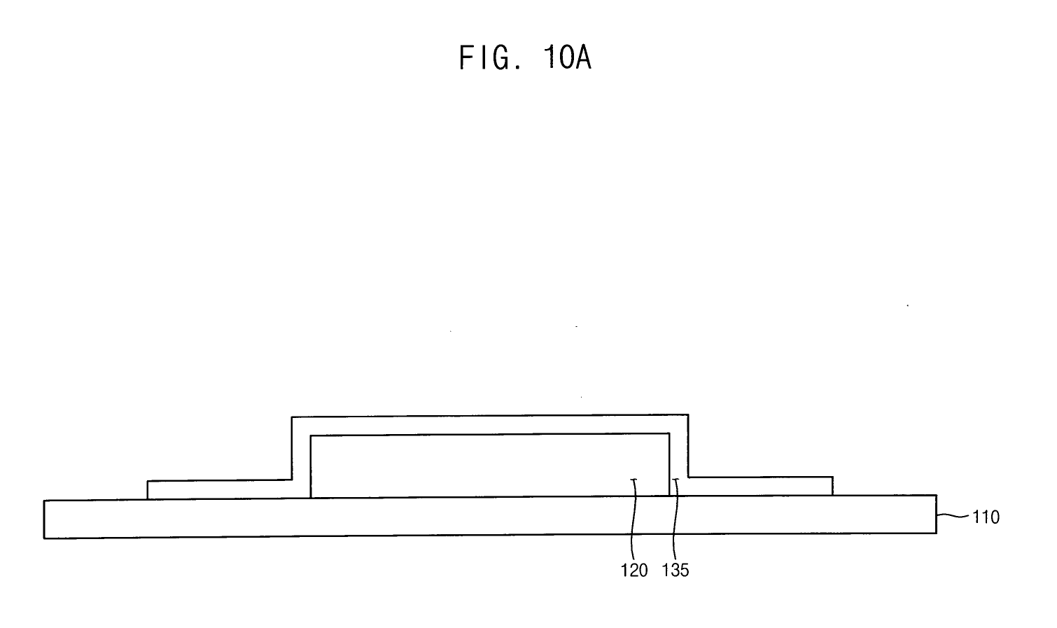

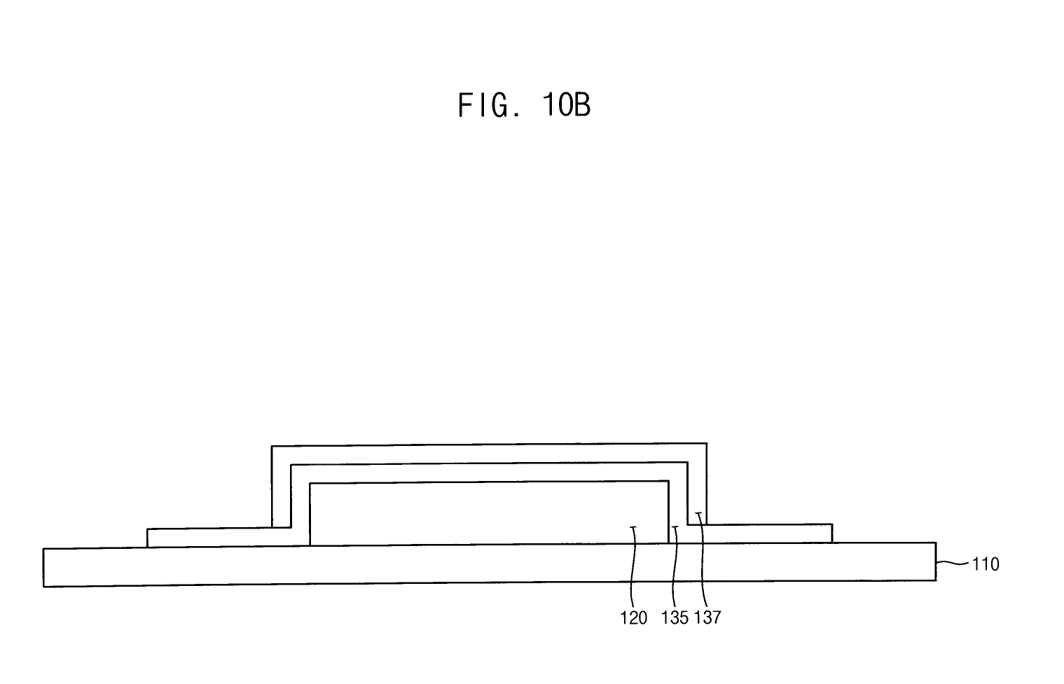

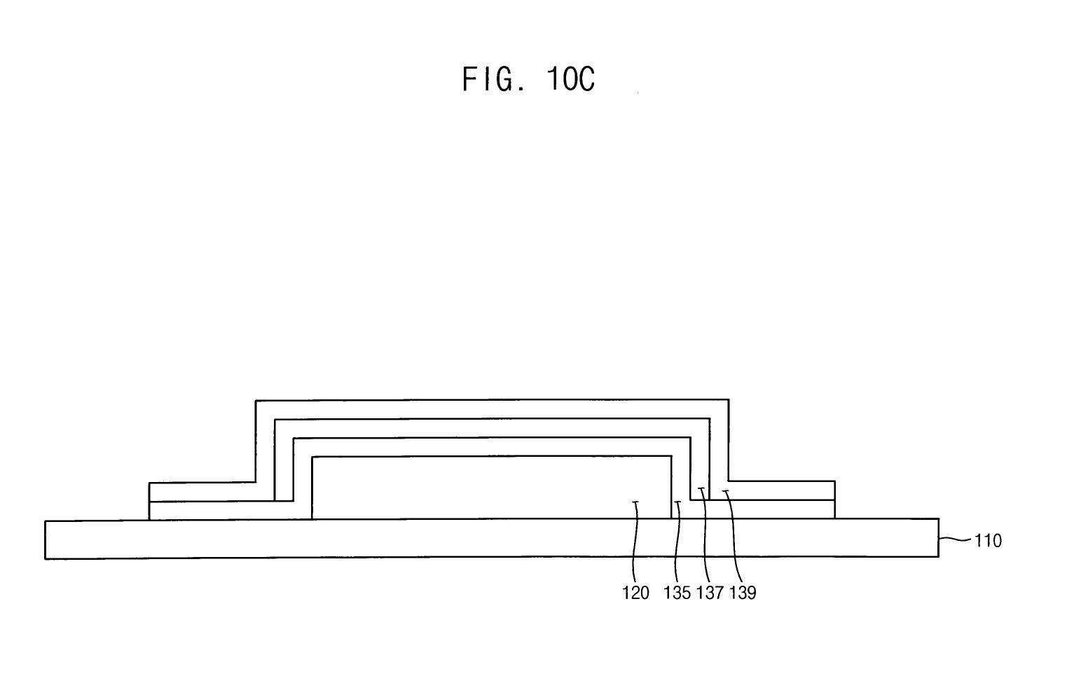

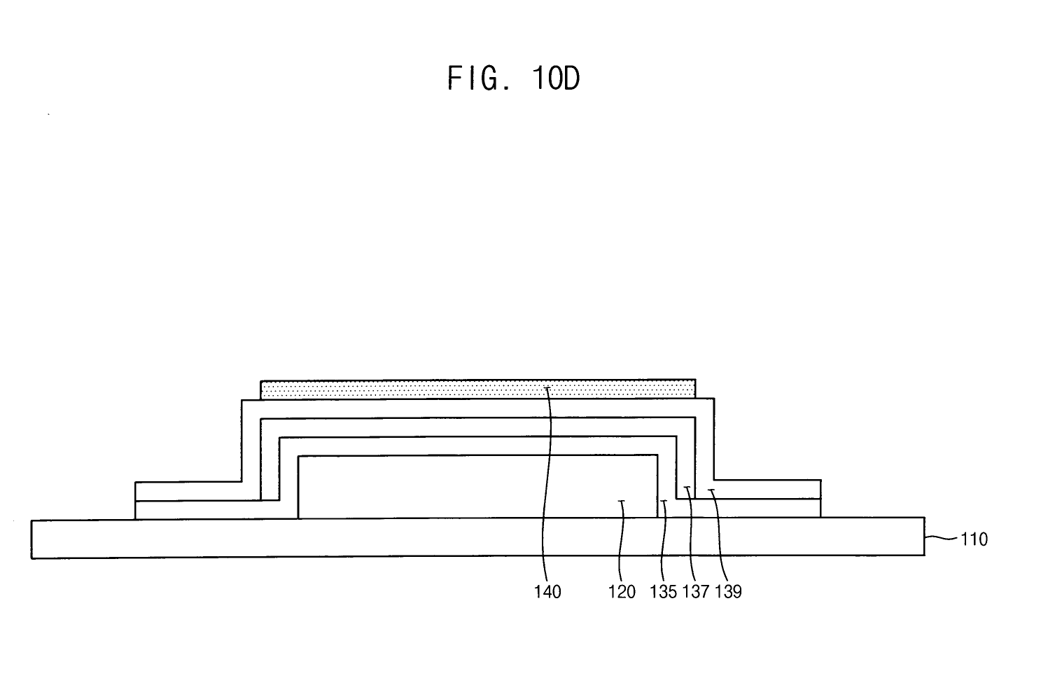

FIG. 9 is a flow chart illustrating a method of manufacturing an organic light emitting display device according to another example embodiment. FIGS. 10A through 10D are cross-sectional views illustrating an example of a method of manufacturing an organic light emitting display device of FIG. 9.

Referring to FIGS. 7 and 9 through 10D, the method of manufacturing the organic light emitting display device may include a step of forming the organic light emitting diodes 120 and thin-film transistors on the first substrate 110 (S210), a step of forming the first inorganic layer 135 that covers the organic light emitting diodes 120 (S220), a step of forming the third organic layer 137 including the monomer on the first inorganic layer 135 (S230), a step of hardening the third organic layer 137 (S240), a step of forming the second inorganic layer 139 that covers the third organic layer 137 (S250), a step of forming the inner filling layer 140 including the monomer on the second inorganic layer 139 (S260), a step of combining the first substrate 110 and the second substrate 160 (S270), a step of hardening the inner filling layer 140 (S280), and a step of sealing between the first substrate 110 and the second substrate 160 by a sealing member 150 (S290).

As shown in FIG. 10A, the organic light emitting diodes 120 may be formed on the first substrate 110. The first inorganic layer 135 may be formed to cover the organic light emitting diodes 120.

The organic light emitting diodes 120 may be formed on the first substrate 110 on which the thin-film transistor is formed. Each of the organic light emitting diodes 120 may include a first electrode, an intermediate layer, and a second electrode.

The first inorganic layer 135 may be formed to cover the organic light emitting diodes 120. The first inorganic layer 135 may prevent the permeation of moisture and gas, because the first inorganic layer 135 has high density. In one embodiment, the first inorganic layer 135 may include at least one of silicon oxide (SiOx), silicon nitride (SiNx), titanium oxide (TiOx), aluminum oxide (AlOx), and silicon oxynitride (SiOxNy). In one embodiment, the first inorganic layer 135 may be formed by a chemical vapor deposition (CVD) method.

As shown in FIG. 10B, the third organic layer 137 including an unhardened monomer may be formed to cover the first inorganic layer 135. The third organic layer 137 may be hardened by UV rays or other methods. The third organic layer 137 may reduce the stress between the first inorganic layer 135 and the second inorganic layer 139, thereby protecting the organic light emitting diodes 120. In addition, the third organic layer 137 may act as a planarization layer. In one embodiment, the monomer included in the third organic layer 137 may include at least one of an acrylic monomer, a silicon monomer, and an epoxy monomer.

As shown in FIG. 10C, the second inorganic layer 139 may be formed to cover the third organic layer 137. The second inorganic layer 139 may prevent the permeation of moisture and gas, because the second inorganic layer 139 has high density. In one embodiment, the second inorganic layer 139 may include at least one of silicon oxide (SiOx), silicon nitride (SiNx), titanium oxide (TiOx), aluminum oxide (AlOx), and silicon oxynitride (SiOxNy). In one example embodiment, the second inorganic layer 139 may be formed by a chemical vapor deposition (CVD) method.

As shown in FIG. 10D, the inner filling layer 140 including an unhardened monomer may be formed on the second inorganic layer 139. The inner filling layer 140 may be hardened after combining the first substrate 110 and the second substrate 160. Thus, the unhardened monomer included in the inner filling layer 140 may be hardened by UV rays or other methods after combining the first substrate 110 and the second substrate 160, thereby bonding the first substrate 110 and the second substrate 160. In addition, the inner filling layer 140 may prevent deformation of the organic light emitting display device by an external impact. Therefore, the inner filling layer 140 that is hardened may protect the organic light emitting diodes 120 by including hardened monomer material. In one embodiment, the monomer included in the inner filling layer 140 may include at least one of an acrylic monomer, a silicon monomer, and an epoxy monomer.

The first substrate 110 and the second substrate 160 may be combined by the sealing member 150. The sealing member 150 may be enclosed the organic light emitting diodes 120, the first inorganic layer 135, the third organic layer 137, the second inorganic layer 139 and the inner filling layer 140. In one embodiment, the sealing member 150 may include an epoxy resin. When the protection layer 130b is comprised of the first inorganic layer 135, the third organic layer 137, and the second inorganic layer 139, the organic light emitting diodes 120 may be isolated from the moisture and gas. Therefore, the sealing member 150 may improve the durability of the organic light emitting diodes 120, when the sealing member 150 includes the epoxy resin of which adhesion is stronger than the adhesion of the frit.

In this way, the organic light emitting display device of FIG. 7 is manufactured. In addition, the organic light emitting display device may further include a reinforcing member 170. The reinforcing member 170 may enclose the sealing member 150 and may be located between the first substrate 110 and the second substrate 160 to seal between the first substrate 110 and the second substrate 160.

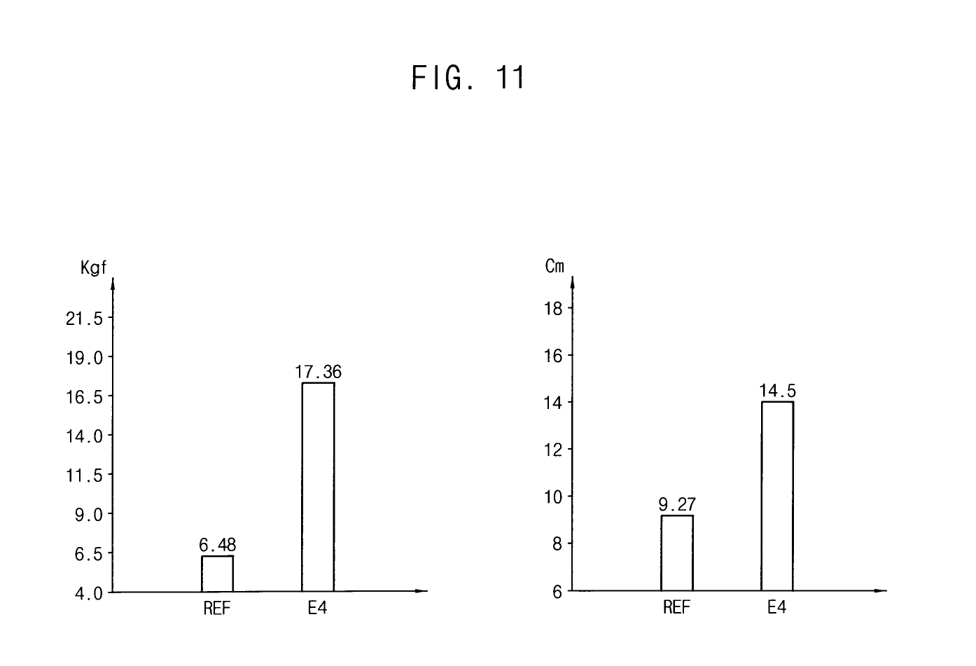

FIG. 11 is a graph for describing an effect of a method of manufacturing an organic light emitting display device of FIG. 9.

Referring to FIG. 11, the organic light emitting display device that is manufactured by the method of FIG. 9 may have a high durability.

The organic light emitting display device may have high peel strength because the organic light emitting display device includes the protection layer having the inorganic layer and the inner filling layer. In a comparative example, a comparative organic light emitting display device REF is sealed between the substrates using the frit without the protection layer and the inner filling layer. In this case, there is an empty space between the organic light emitting diodes and one of the substrates. A peel strength of the comparative organic light emitting display device REF is about 6.48 kgf. In the fourth experimental example, the fourth experimental organic light emitting display device E4 includes the first inorganic layer of which thickness is 1 μm, the third organic layer of which thickness is 2 μm, the second inorganic layer of which thickness is 1 μm, and the inner filling layer of which thickness is 3 μm. Here, each thickness is determined in a region where the pixel defining layer 126 is formed, for example, region D shown in FIG. 8. A peel strength of the fourth experimental organic light emitting display device E4 is about 17.36 kgf. Therefore, the organic light emitting display device including the protection layer, that has the inorganic layer, and inner filling layer may improve the peel strength in about 2.6 times.

The drop weight test, that measures a height in which the organic light emitting display device is fragile when the urethane ball having 300 g weight is dropped, was performed. In a comparative example, a comparative organic light emitting display device REF is sealed between the substrates using the frit without the protection layer and the inner filling layer. A height, in which the comparative organic light emitting display device REF is fragile, was average 9.27 cm. In the fourth experimental example, the fourth experimental organic light emitting display device E4 includes the first inorganic layer of which thickness is 1 μm, the third organic layer of which thickness is 2 μm, the second inorganic layer of which thickness is 1 μm, and the inner filling layer of which thickness is 3 μm. A height, in which the fourth experimental organic light emitting display device E4 is fragile, was average 14.5 cm.

The fourth experimental organic light emitting display device E4 that is manufactured by the method of FIG. 9 has relative high peel strength and high durability in comparison with the comparative organic light emitting display device REF.

Therefore, the organic light emitting display device according to example embodiments may effectively prevent penetration of moisture or gas and may have high durability by including the protection layer and inner filling layer.

The present inventive concept may be applied to an electronic device having an organic light emitting display device. For example, the present inventive concept may be applied to a television, a computer monitor, a laptop, a digital camera, a cellular phone, a smart phone, a smart pad, a personal digital assistant (PDA), a portable multimedia player (PMP), a MP3 player, a navigation system, a game console, a video phone, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An organic light emitting display device, comprising:
a first substrate;
a second substrate opposing the first substrate;
a plurality of organic light emitting diodes disposed on the first substrate;
a protection layer covering the organic light emitting diodes;
an inner filling layer disposed between the protection layer and the second substrate, the inner filling layer including a hardened monomer material; and
a sealing member located between the first substrate and the second substrate to seal between the first substrate and the second substrate, the sealing member enclosing the organic light emitting diodes, the protection layer, and the inner filling layer.

2. The device of claim 1, wherein the inner filling layer directly contacts the second substrate and the protection layer.

3. The device of claim 1, wherein the hardened monomer material included in the inner filling layer is generated by hardening a monomer after combining the first substrate and the second substrate, and wherein the hardened monomer material includes at least one of a hardened acrylic monomer, a hardened silicon monomer, and a hardened epoxy monomer.

4. The device of claim 1, wherein the protection layer includes:
a first organic layer covering the organic light emitting diodes, the first organic layer including a hardened monomer material; and
a second organic layer covering the first organic layer, the second organic layer including a hardened monomer material.

5. The device of claim 4, wherein a thickness of the second organic layer is greater than a thickness of the first organic layer

6. The device of claim 4, wherein the sealing member includes a frit.

7. The device of claim 1, wherein the protection layer includes:
a first inorganic layer covering the organic light emitting diodes;
a third organic layer disposed on the first inorganic layer; and
a second inorganic layer covering the third organic layer.

8. The device of claim 7, wherein the first inorganic layer and the second inorganic layer include at least one of silicon oxide (SiOx), silicon nitride (SiNx), titanium oxide (TiOx), aluminum oxide (AlOx), and silicon oxynitride (SiOxNy).

9. The device of claim 7, wherein the sealing member includes an epoxy resin.

10. The device of claim 7, wherein the first inorganic layer contacts with the second inorganic layer in an outer region of the organic light emitting diodes, and
wherein the second inorganic layer contacts with the sealing member in the outer region of the organic light emitting diodes.

11. The device of claim 1, further comprising:
a reinforcing member enclosing the sealing member, the reinforcing member located between the first substrate and the second substrate to seal between the first substrate and the second substrate.

12. A method of manufacturing an organic light emitting display device, the method comprising:
forming a plurality of organic light emitting diodes on a first substrate;
forming a protection layer covering the organic light emitting diodes;
forming an inner filling layer on the protection layer, the inner filling layer including a monomer;
combining the first substrate and a second substrate opposing the first substrate;
hardening the inner filling layer after the first substrate and the second substrate are combined; and
sealing between the first substrate and the second substrate by a sealing member that is located between the first substrate and the second substrate, the sealing member enclosing the organic light emitting diodes, the protection layer, and the inner filling layer.

13. The method of claim 12, wherein forming the protection layer includes:
forming a first organic layer including a monomer to cover the organic light emitting diodes;
hardening the first organic layer;
forming a second organic layer including a monomer to cover the first organic layer; and
hardening the second organic layer.

14. The method of claim 13, wherein a thickness of the second organic layer is greater than a thickness of the first organic layer.

15. The method of claim 13, wherein the sealing member includes a frit.

16. The method of claim 12, wherein forming the protection layer includes:
forming a first inorganic layer covering the organic light emitting diodes;
forming a third organic layer including a monomer on the first inorganic layer;
hardening the third organic layer; and
forming a second inorganic layer covering the third organic layer.

17. The method of claim 16, wherein the first inorganic layer and the second inorganic layer are formed by a chemical vapor deposition (CVD) method.

18. The method of claim 16, wherein the first inorganic layer and the second inorganic layer include at least one of silicon oxide (SiOx), silicon nitride (SiNx), titanium oxide (TiOx), aluminum oxide (AlOx), and silicon oxynitride (SiOxNy).

19. The method of claim 16, wherein the sealing member includes an epoxy resin.

20. The method of claim 12, wherein the monomer included in the inner filling layer includes at least one of an acrylic monomer, a silicon monomer, and an epoxy monomer.
